(19) United States
(12) Patent Application Publication
(10) Pub. No.: US 2025/0216773 A1
(43) Pub. Date: Jul. 3, 2025

(54) System and Method for Inspecting Mask

(71) Applicant: TAIWAN SEMICONDUCTOR MANUFACTURING COMPANY, LTD., Hsinchu (TW)

(72) Inventors: Yen-Hsun CHEN, Taipei City (TW); Chao-Ting CHEN, Taichung City (TW); Chih-Feng LU, New Taipei City (TW); Han-Lung CHANG, Kaohsiung City (TW); Li-Jui CHEN, Hsinchu City (TW)

(73) Assignee: TAIWAN SEMICONDUCTOR MANUFACTURING COMPANY, LTD., Hsinchu (TW)

(21) Appl. No.: 18/397,809

(22) Filed: Dec. 27, 2023

(51) Int. Cl. G03F 1/84; G01N 21/956

(52) U.S. Cl. CPC G03F 1/84; G01N 21/956; G01N 2021/95676; G01N 2201/023

(57) ABSTRACT

A method for inspecting a mask is provided. The method includes placing the mask on a stage of an inspection tool; using a fan assembly, introducing a gas flow into the inspection tool; performing an environmental pressure control over the inspection tool; and capturing an image of the mask. The environmental pressure control includes monitoring an in-tool pressure inside the inspection tool and an out-tool pressure outside the inspection tool; determining whether the pressure difference between the in-tool pressure and the out-tool pressure is out of an acceptable range; and in response the determination determines that the pressure difference between the in-tool pressure and the out-tool pressure is out of the acceptable range, adjusting the power of the fan assembly.

### BACKGROUND

Photolithography is a process by which a mask having a pattern is irradiated with light to transfer the pattern onto a photosensitive material overlying a semiconductor substrate. Over the history of the semiconductor industry, smaller integrated chip minimum features sizes have been achieved by reducing the exposure wavelength of optical lithography radiation sources to improve photolithography resolution. Extreme ultraviolet (EUV) lithography, which uses extreme ultraviolet (EUV) light is a promising next-generation lithography solution for emerging technology nodes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a system for inspecting a mask according to some embodiments of the present disclosure.

FIG. 2 is a flow chart of a method for inspecting a mask according to some embodiments of the present disclosure.

FIG. 3 is a flow chart of performing an environmental pressure control over an inspection tool according to some embodiments of the present disclosure.

FIG. 4 is a graph illustrating aberration variation versus a pressure difference between inside and outside an inspection tool according to some embodiments of the present disclosure.

FIG. 5 is an operational sequence diagram for operating an inspection system according to some embodiments of the present disclosure.

FIG. 6A is a pre-exposure sub-image at an interested region of a mask according to some embodiments of the present disclosure.

FIG. 6B is a post-exposure sub-image of the interested region of the mask according to some embodiments of the present disclosure.

FIG. 6C is a defect sub-image of the interested region of the mask according to some embodiments of the present disclosure.

FIG. 7 is a schematic view of a lithography system according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The advanced lithography process, method, and materials described in the embodiments of the present disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to some embodiments of the present disclosure.

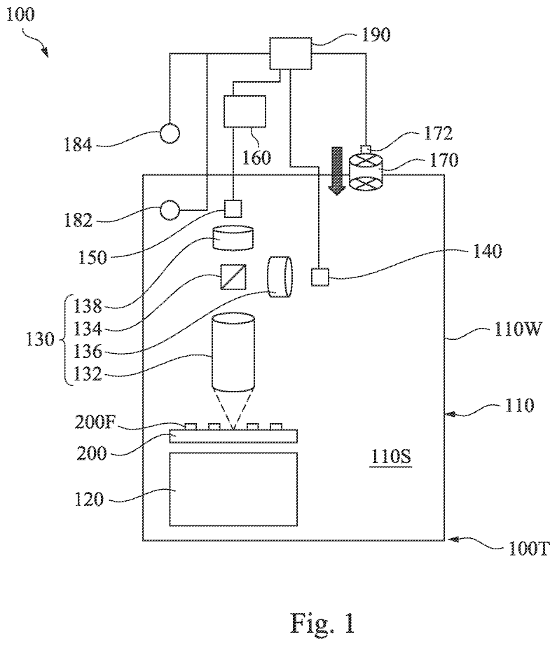

FIG. 1 is a system 100 for inspecting a mask 200 according to some embodiments of the present disclosure. The inspection system 100 include an inspection tool 100T, including a mask stage 120, an optical assembly 130, a light source 140, a detector 150. The inspection tool 100T may further include a fan assembly 170 for cooling the elements inside the inspection tool 100T. The inspection system 100 may also include pressure sensors 182 and 184 for performing an environmental pressure control over the inspection tool 100T. In the context, the inspection system 100 may also be referred to as an inspection apparatus.

The inspection tool 100T may has a cabinet 110, which has a wall 110W surrounding a space 110S. In some embodiments, the mask stage 120, the optical assembly, and the pressure sensor 182 are disposed the space 110S surrounded by the wall 110W. The mask 200 is placed on the mask stage 120 in facilitate movement to different regions of the mask 200 underneath the optics. The mask stage 120 may comprise an X-Y stage or an R-θ stage. By way of examples, one or more motor mechanisms may each be formed from a screw drive and stepper motor, linear drive with feedback position, or band actuator and stepper motor. In some embodiments, the mask stage 120 can adjust the height of the mask 200 during inspection to maintain focus. In other embodiments, the objective lens 132 can be adjusted to maintain focus.

In this context, the terms, mask, reticle, and photomask are used interchangeably. In the present embodiments, the mask 200 is a reflective mask for extreme ultraviolet (EUV) lithography system. One exemplary structure of the mask 200 includes a substrate with a low thermal expansion material (LTEM). For example, the LTEM may include TiO₂ doped SiO₂, or other suitable materials with low thermal expansion. The mask 200 includes a reflective multi-layer deposited on the substrate. The reflective multi-layer includes plural film pairs, such as molybdenum-silicon (Mo/Si) film pairs (e.g., a layer of molybdenum above or below a layer of silicon in each film pair). Alternatively, the reflective multi-layer may include molybdenum-beryllium (Mo/Be) film pairs, or other suitable materials that are configurable to highly reflect the EUV light. The mask 200 may further include a capping layer, such as ruthenium (Ru), disposed on the reflective multi-layer for protection. The mask 200 further includes an absorption layer, such as a tantalum boron nitride (TaBN) layer, deposited over the reflective multi-layer. The absorption layer is patterned to define a layer of an integrated circuit (IC). For example, the mask 200 includes an absorptive pattern 200F. The mask 200 may have other structures or configurations in various embodiments.

The light source 140 may include one or more lasers and/or a broad-band light source. One example of the light source 140 is a quasi-continuous wave laser. In certain embodiments, the light source 140 may provide high pulse repetition rate, low-noise, high power, stability, reliability, and extendibility. It is noted that while an EUV scanner operates at 13.5 nm wavelength, an inspection tool for an EUV reticle does not have to operate at the same wavelength. For example, the light source 140 may emit deep UV (DUV) and/or vacuum UV (VUV) radiation.

The optical assembly 130 including an objective lens 132 can direct that radiation towards, and focuses it on, the mask 200. Optical assembly 130 may also comprise mirrors, lenses, and/or beam splitters. Light reflected or scattered from the mask 200 can be collected, directed, and focused by the optical assembly 130 onto the detector 150. In illustrated embodiments, the optical assembly 130 includes a beam splitter 134 for combining an optical path from the light source 140 to the mask 200 and an optical path from the mask 200 to the detector 150. In some embodiments, the optical assembly 130 may have mirror and/or lenses 136 for directing light from the light source 140 to the mask 200, and the optical assembly 130 may have mirror and/or lenses 138 for directing light from the mask 200 to the detector 150.

Detector 150 may include one, or more, of the image sensors described herein, including back-illuminated charged coupled device (CCD) sensors, back-illuminated complementary metal oxide semiconductor (CMOS) sensors, and electron-bombarded images sensors incorporating a back-thinned solid-state image sensor. Detector 150 may include a two-dimensional array sensor or a one-dimensional line sensor. In some embodiments, the detector 150 are synchronized with the laser pulses of the light source 140. In certain embodiments, the detector 150 is a time delay integration (TDI) detector. A TDI detector accumulates multiple exposures of the same area of the inspected surface, effectively increasing the integration time available to collect incident light. The detector 150 may be also coupled with a processor system (or a signal processing device) 160, which may include an analog-to-digital converter configured to convert analog signals from the sensors of the detector 150 to digital signals or images for processing. The processor system 160 may be configured to analyze intensity, phase, and/or other characteristics of one or more images.

The processor system 160 may also be coupled with a controller 190. The controller 190 may be any suitable combination of software and hardware. For example, the controller may include a processor, coupled to input/output ports, and one or more memories via appropriate buses or other communication mechanisms. The processor and memory may be programmed to implement instructions of the method according to some embodiments of the present disclosure. The controller 190 may also include one or more input devices (e.g., a keyboard, mouse) for providing user input, such as changing focus depths, polarization settings, wavelength selection, or setting up an inspection recipe. The controller 190 may also be coupled with various components of the system 100, such as the mask stage 120, the light source 140, the optical assembly 130, the fan assembly 170, and the pressure sensors 182 and 184, for controlling, for example, a mask position (e.g., focusing and scanning), zoom setting, and other inspection parameters and configurations of the inspection system elements.

Because such information and program instructions may be implemented on a specially configured computer system, such a system includes program instructions/computer code for performing various operations described herein that can be stored on a computer readable media. Examples of machine-readable media include, but are not limited to, magnetic media such as hard disks, floppy disks, and magnetic tape; optical media such as CD-ROM disks; magneto-optical media such as optical disks; and hardware devices that are specially configured to store and perform program instructions, such as read-only memory devices (ROM) and random access memory (RAM). Examples of program instructions include both machine code, such as produced by a compiler, and files containing higher level code that may be executed by the computer using an interpreter.

The fan assembly 170 is mounted on the wall 110W to introduce air or gases (or an air flow or a gas flow) outside the inspection tool 100T (e.g., outside the space 110S) into the inspection tool 100T (e.g., into the space 110S), thereby cooling down the optical assembly 130 in the space 110S. By introducing the gas into the space 110S, a temperature of the optical assembly 130 may be lowered. In the illustrated embodiments, the fan assembly 170 is located on a top side of the cabinet 110 of the inspection tool 100T. In some alternative embodiments, the fan assembly 170 may be located on one or more of the top side, a bottom side, and lateral sides of the cabinet 110 of the inspection tool 100T.

The controller 190 can adjust the trust force of the fan assembly 170. For example, a power supply 172 for the fan assembly 170 is electrically coupled with the controller 190. The controller 190 may control the power of the power supply 172 supplied to the fan assembly 170, thereby adjusting the trust force of the fan assembly 170. In some embodiments, the power supplied to the fan assembly 170 is positively correlated with the trust force of the fan assembly 170. Thus, for increasing the trust force of the fan assembly 170, the power supplied to the fan assembly 170 is increased; and for decreasing the trust force of the fan assembly 170, the power supplied to the fan assembly 170 is lowered. In the illustrated embodiments, the fan assembly 170 has a single air fan, and a trust force of the air fan can be controlled and adjusted by the controller 190. In some alternative embodiments, the fan assembly 170 may have plural air fans, and trust forces of each of the air fans can be independently controlled and adjusted by the controller 190.

The pressure sensors 182 and 184 are respectively disposed inside the inspection tool 100T (e.g., in the space 110S) and outside the inspection tool 100T (e.g., outside the space 110S), thereby monitoring/detecting/sensing pressures inside the inspection tool 100T (e.g., in the space 110S) and outside the inspection tool 100T (e.g., outside the space 110S). The detected pressured may be referred to as an in-tool pressure and an out-tool pressure, respectively. The controller 190 may electrically connected with the pressure sensors 182 and 184 and can obtain signals carrying information (e.g., the in-tool pressure and the out-tool pressure) from these pressure sensors 182 and 184.

Aberration instability may be found during inspecting an EUV mask. The aberration instability may be caused by fluctuations in environmental pressure surrounding the optical assembly 130. And, when supplying the fan assembly 170 with a constant power, the trust force of the fan assembly 170 is sensitive to changes in environmental pressure. In some embodiments of the present disclosure, a method is provided to apply an environmental pressure control by adjusting the power of the fan assembly 170 to compensate pressure fluctuations, thereby lowering aberration instability and improving tool availability.

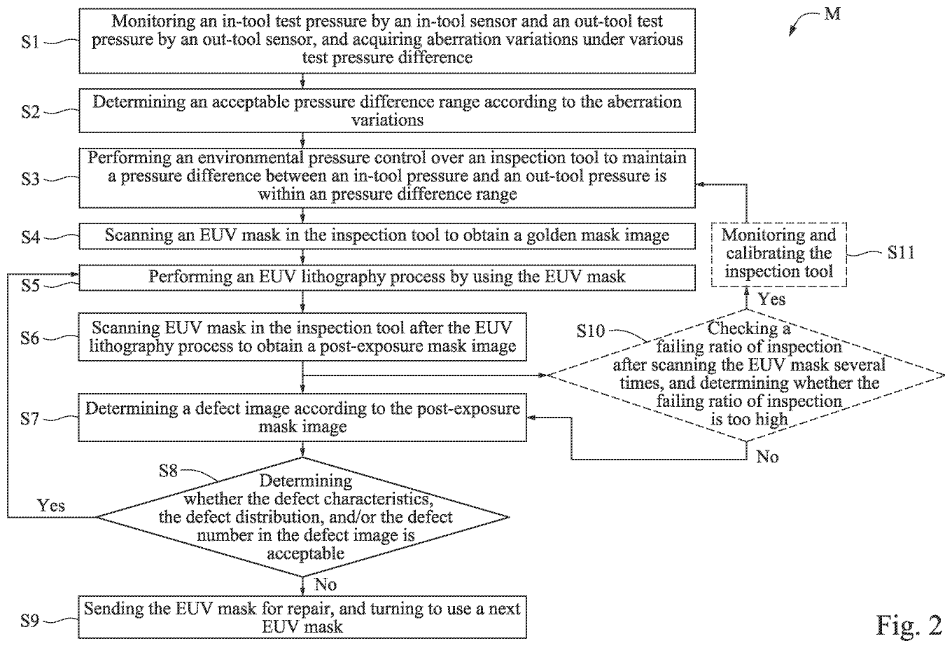

FIG. 2 is a flow chart of a method M for inspecting a mask according to some embodiments of the present disclosure. The method M may include steps S1-S9. At step S1, an in-tool test pressure is monitored by an in-tool sensor and an out-tool test pressure is monitored by an out-tool sensor, and aberration variations are acquired under various test pressure difference. At step S2, an acceptable pressure difference range is determined according to the aberration variations. At step S3, an environmental pressure control is performed over an inspection tool to maintain a pressure difference between an in-tool pressure and an out-tool pressure is within an acceptable range. At step S4, an EUV mask is scanned inn the inspection tool to obtain a golden mask image. At step S5, an EUV lithography process is performed by using the EUV mask. At step S6, the EUV mask is scanned in the inspection tool after the EUV lithography process to obtain a post-exposure mask image. At step S7, a defect image is determined according to the post-exposure mask image. At step S8, it is determined whether the defect characteristics, the defect distribution, and/or the defect number in the defect image is acceptable. At step S9, the EUV mask is sent for repair, and the operator may turn to use a next EUV mask. At step S10, a failing ratio of inspection is checked after scanning the EUV mask several times, and it is determined whether the failing ratio of inspection is too high. At step S11, the inspection tool is monitored and calibrated. It is understood that additional steps may be provided before, during, and after the steps S1-S11 shown by FIG. 2, and some of the steps described below can be replaced or eliminated for additional embodiments of the method. The order of the operations/processes may be interchangeable. The inspection tool 100T may be suitable for inspecting semiconductor devices or wafers and optical reticles, including EUV reticles or masks. Other types of samples may also be inspected using the method M.

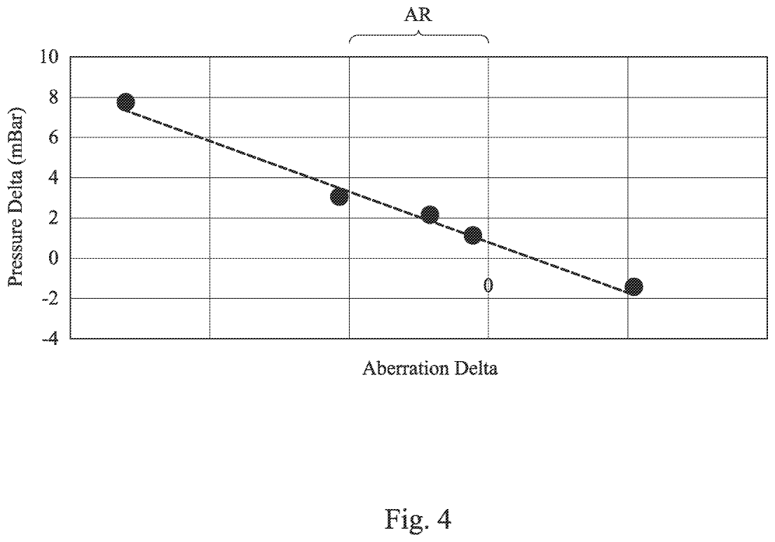

Reference is made both to FIGS. 1 and 2. The method M begins at step S1, where an in-tool test pressure is monitored by an in-tool sensor and an out-tool test pressure is monitored by an out-tool sensor, and aberration variations are acquired under various test pressure differences. The inspection tool 100T may repeatedly scan a test sample (e.g., a test EUV mask or a target EUV mask). The processor system 160 may receive the scan results. The pressure sensors 182 and 184 may monitor the in-tool test pressure and the out-tool test pressure at each scan, and send signals carrying information about the in-tool test pressure and the out-tool test pressure to the controller 190. The controller 190 may calculate a test pressure difference between the in-tool test pressure and the out-tool test pressure at each scan. For example, the test pressure difference is obtained by subtracting the out-tool test pressure from the in-tool test pressure. And, the processor system 160 and/or the controller 190 may acquire aberration variations of each scan by any suitable aberration determination technique. For example, the aberration variations may be determined according to one or more operating parameters, such as wavelength range, polarization setting, zoom setting, numerical aperture (NA), etc. As such, by repeatedly scan the test sample and real-time monitoring the in-tool and out-tool test pressures, a relationship between aberration variations and the test pressure differences is obtained, as shown in FIG. 4. FIG. 4 is a graph illustrating aberration variation versus pressure differences between inside and outside an inspection tool according to some embodiments of the present disclosure. The horizontal axis is aberration variation, and the vertical axis is the pressure difference, which is equal to the in-tool pressure subtracted by the out-tool pressure. It can be evidenced from FIG. 4 that aberration is very sensitive to the environmental pressure fluctuation.

The method M proceeds to the step S02 where an acceptable pressure difference range is determined according to the aberration variations. In some embodiments, considering an ideal value of an aberration variation is zero, aberration variations within a tolerance range of about 0.3 from zero may be considered as acceptable. Stated differently, the aberration variations ranging from −0.3 to about +0.3 are acceptable. Thus, in FIG. 4, the test pressure difference range AR corresponding to the acceptable range of the aberration variations, is determined as the acceptable pressure difference range. For example, in some embodiments, the acceptable pressure difference range AR is in a range from about 0 mBar to about 2 mBar. If the pressure difference is out of the acceptable pressure difference range AR, the aberration variations may be too large to inspect the EUV mask well. In some other embodiments, the ideal value of an aberration variation and the tolerance range for aberration variation may change depending on operator's settings, such that the acceptable pressure difference range AR may vary accordingly.

The method M proceeds to step S3, where an environmental pressure control is performed over an inspection tool 100T to maintain a pressure difference between an in-tool pressure and an out-tool pressure within an acceptable range. The following process steps S4-S6 is performed under the environmental pressure control for maintaining or reducing the aberration variation. Stated differently, during the step S3 of performing the environmental pressure control, the process steps S4-S6 are performed. In other words, the environmental pressure control includes performing a real-time adjustment on a gas trust force (or power) of the fan assembly 170 for maintaining or reducing g the aberration variation.

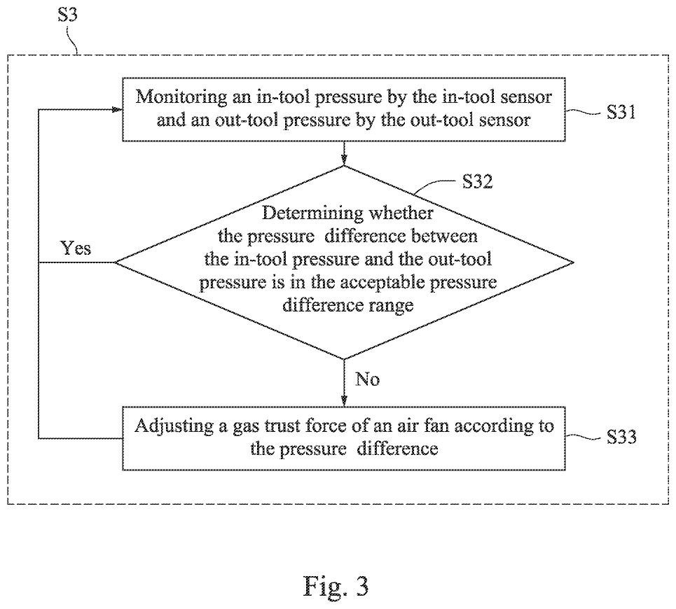

The step S3 is further illustrated in FIG. 3. FIG. 3 is a flow chart of performing an environmental pressure control over the inspection tool 100T (i.e., step 3) according to some embodiments of the present disclosure. The step S3 may include steps S31-S33. At step S31, an in-tool pressure is monitored by an in-tool sensor, and an out-tool pressure is monitored by an out-tool sensor. At step S32, it is determined whether the pressure difference between the in-tool pressure and the out-tool pressure is in the acceptable pressure difference range. At step S33, a gas trust force of the fan assembly is adjusted according to the pressure difference. It is understood that additional steps may be provided before, during, and after the steps S31-S33 shown by FIG. 3, and some of the steps described below can be replaced or eliminated for additional embodiments of the method. The order of the operations/processes may be interchangeable.

At step S31, an in-tool pressure is monitored by the in-tool pressure sensor 182, and an out-tool pressure is monitored by the out-tool pressure sensor 184. The in-tool pressure sensor 182 and the out-tool pressure sensor 184 may respectively send signals carrying information about the in-tool pressure and the out-tool pressure to the controller 190. Then, the controller 190 may calculate a pressure difference between the in-tool pressure and the out-tool pressure. For example, the pressure difference is obtained by subtracting the out-tool pressure from the in-tool pressure.

At step S32, it is determined whether the pressure difference between the in-tool pressure and the out-tool pressure is in the acceptable pressure difference range. If the controller 190 determines the pressure difference is in the acceptable pressure difference range, the method goes back to the step S31 to keep monitoring the in-tool pressure and the out-tool pressure. If the controller 190 determines the pressure difference is out of the acceptable pressure difference range, the method proceeds to the step S33 where a gas trust force of the fan assembly 170 is adjusted according to the pressure difference. In the context, the gas trust force of the fan assembly 170 is considered as being positive correlated to the power of the fan assembly 170.

In some embodiments, the gas trust force of the fan assembly 170 (or the power of the fan assembly 170) is adjusted for allowing the pressure difference to approach the acceptable pressure difference range. Stated differently, the gas trust force of the fan assembly 170 (or the power of the fan assembly 170) is adjusted for reducing a difference between the pressure difference and the acceptable pressure difference range. For example, if the pressure difference is positive (e.g., the in-tool pressure is greater than the out-tool pressure) and out of the acceptable pressure difference range, the controller 190 may control the power supply 172 to decrease the power supplied to the fan assembly 170, thereby decreasing the gas trust force of the fan assembly 170 from outside tool toward inside tool, which in turn will lower the in-tool pressure. If the pressure difference is negative (e.g., the in-tool pressure is less than the out-tool pressure) and out of the acceptable pressure difference range, the controller 190 may control the power supply 172 to increase the power supplied to the fan assembly 170, thereby increasing the gas trust force of the fan assembly 170 from outside tool toward inside tool, which in turn will increase the in-tool pressure.

In some embodiments, the increment and/or the decrement of the power supplied to the fan assembly 170 can be calculated and determined by the controller 190 based on the measured pressure difference (and/or the measured in-tool and out-tool pressures). In such embodiments, by adjusting the power supplied to the fan assembly 170 by the determined increment and/or the decrement value, the pressure difference may fall in the acceptable pressure difference range. For example, using the controller 190, the increment and/or the decrement of the power supplied to the fan assembly 170 can be determined by the formula/model/algorithm based on the measured pressure difference (and/or the measured in-tool and out-tool pressures), in which suitable tests between the power supplied to the fan assembly 170 and the pressure difference (and/or the in-tool and out-tool pressures) may be performed to develop the formula/model/algorithm therebetween in advance. The method goes back to the step 31 to keep monitoring the in-tool pressure and the out-tool pressure. In some other embodiments, after adjusting the power supplied to the fan assembly 170 with the determined increment and/or the decrement value, the pressure difference may be still out of the acceptable pressure difference range. In such embodiments, by repeating the step S31-S33, the power supplied to the fan assembly 170 can be adjusted to a suitable value, which allows the pressure difference to be within the acceptable pressure difference range.

In some alternative embodiments, the increment and/or the decrement of the power supplied to the fan assembly 170 may be a small constant value, and the method goes back to the step 31 and repeats the step S31-S33. In each time of repeating the steps S31-S33, the power supplied to the fan assembly 170 is adjusted by the small constant value. After repeating the step S31-S33 several times, the power supplied to the fan assembly 170 can be adjusted to a suitable value, which allows the pressure difference to be within the acceptable pressure difference range.

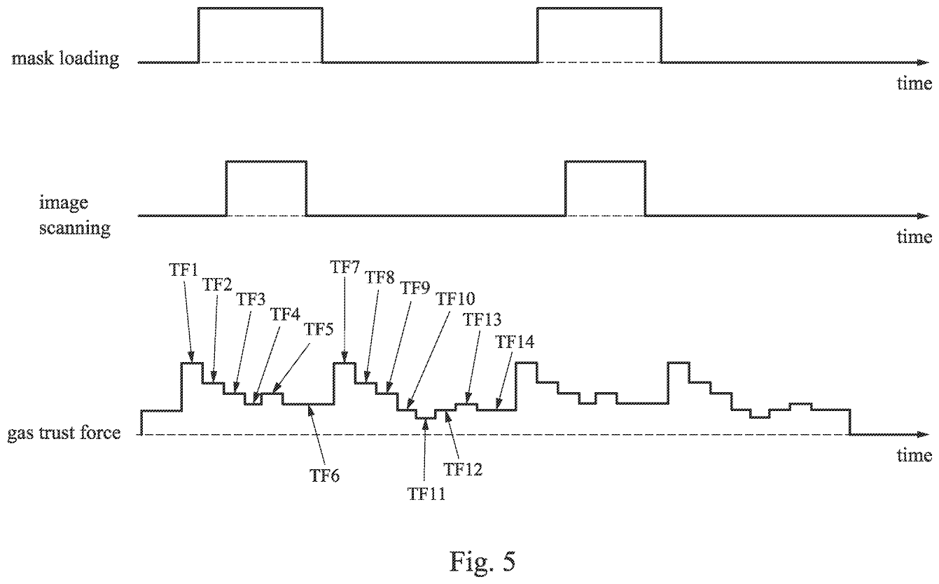

FIG. 5 is an operational sequence diagram for operating an inspection system 100 according to some embodiments of the present disclosure. Reference is made both to FIGS. 1 and 5. In some embodiments, in response to the real-time monitored pressure difference, the gas trust force of the fan assembly 170 is adjusted in real time. For example, the fan assembly 170 is controlled to introduce a gas flow into the inspection tool 100T by a gas trust force TF1-TF14 in a sequence, in which any adjacent two of the gas trust force TF1-TF14 are different from each other. For example, the gas trust force TF1 is greater than the gas trust force TF2. The gas trust force TF2 is greater than the gas trust force TF3. The gas trust force TF3 is greater than the gas trust force TF4. The gas trust force TF4 is less than the gas trust force TF5. The gas trust force TF5 is greater than the gas trust force TF6. The gas trust force TF6 is less than the gas trust force TF7. The gas trust force TF7 is greater than the gas trust force TF8. The gas trust force TF8 is greater than the gas trust force TF9. The gas trust force TF9 is greater than the gas trust force TF10. The gas trust force TF10 is greater than the gas trust force TF11. The gas trust force TF11 is less than the gas trust force TF12. The gas trust force TF12 is less than the gas trust force TF13. The gas trust force TF13 is greater than the gas trust force TF14. In FIG. 5, the real-time gas trust force of the fan assembly 170 is illustrated as a step function. In some other embodiments, the real-time gas trust force of the fan assembly 170 may act a smooth function.

The amplitude, frequency, and sequence of the gas trust force shown in FIG. 5 may correspond to the power of the fan assembly 170. In some embodiments, the gas trust force shown in FIG. 5 may be considered as a power signal provided to the fan assembly 170, in which any adjacent two of powers corresponding to the gas trust force TF1-TF14 are different from each other.

The fan assembly 170 may be controlled and adjusted to introduce the gas flow with the gas trust forces TF2-TF6 when the mask 200 is loaded in the inspection tool 100T, for example, being placed on the mask stage 120. Furthermore, the fan assembly 170 may be controlled and adjusted to introduce the gas flow with the gas trust forces TF3-TF6 when the mask 200 is scanned in the inspection tool 100T, for obtaining mask image. The fan assembly 170 may be controlled and adjusted to introduce the gas flow with the gas trust forces TF7-TF14 when the mask 200 is unloaded, for example, being removed from the mask stage 120. The amplitude, frequency, and sequence illustrated is merely examples given for easily describing the operation of the inspection system 100. In some embodiments, the gas trust force of the fan assembly 170 may be adjusted in response to the pressure difference with suitable amplitude, frequency, and sequence according to system requirements.

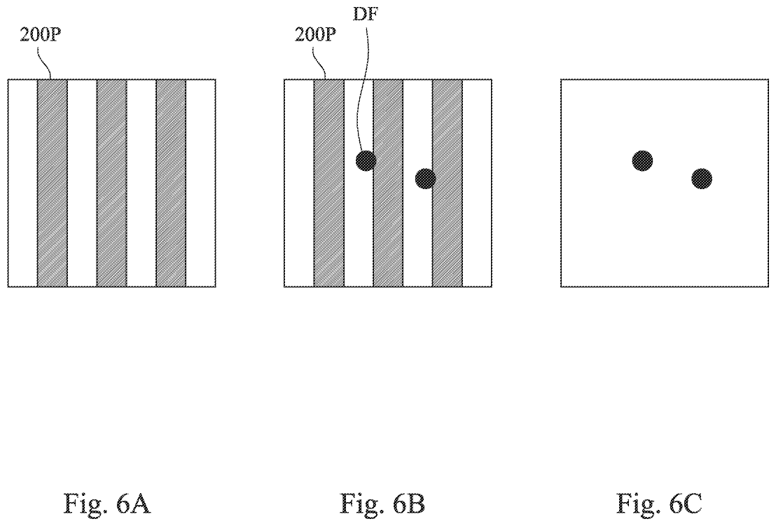

Reference is made back to FIGS. 1 and 2. The method M then proceeds to the step S4 where the EUV mask 200 is scanned in the inspection tool 100T to obtain a golden mask image. The scanning process may include sequentially capturing sub-images of plural interested regions of the EUV mask 200. For example, the mask stage 120 may move the EUV mask 200, such that the interested regions of the EUV mask 200 are sequentially moved to a inspect position where the light from the light source 140 is impinged. The sub-images of the interested regions of the EUV mask 200 are combined as a whole mask image. At this stage, since the mask image is scanned before an EUV lithography process at this stage, the mask image may be referred to as a pre-exposure mask image, golden mask image, or a reference mask image. And, the sub-images of the interested regions of the EUV mask 200 at this stage may be referred to as pre-exposure sub-images, golden sub-images, or reference sub-images. FIG. 6A is a pre-exposure sub-image at an interested region of a EUV mask according to some embodiments of the present disclosure. Since the EUV mask has not experienced any lithography processes, the absorptive pattern 200F is clearly shown in FIG. 6A with little or no defects.

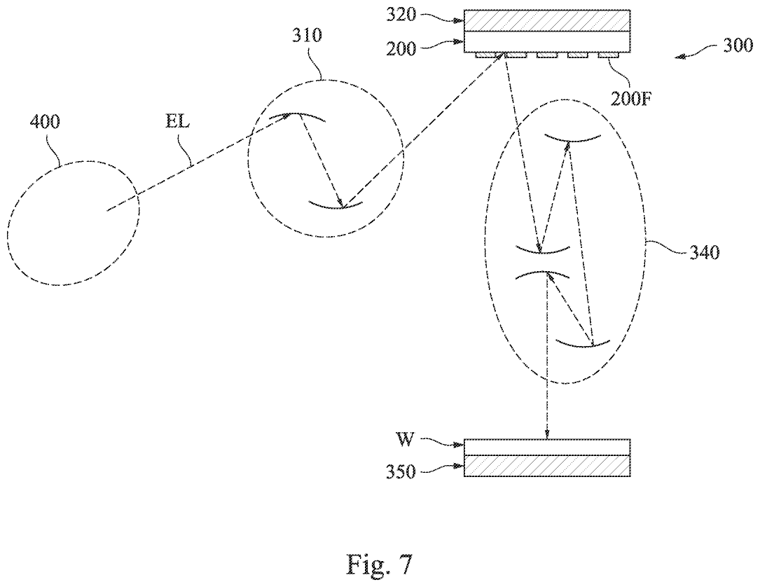

Reference is made back to FIGS. 1 and 2. The method M proceeds to the step S5 where an EUV lithography process is performed by using the EUV mask 200. For example, as illustrated in FIG. 7 later, the EUV mask 200 is mounted on a mask stage 320 of the lithography system 300, and reflecting a EUV light EL from the radiation source 400 to a semiconductor substrate W coated with a resist layer sensitive to the EUV light EL. Details of the lithography system 300 will be illustrated later with FIG. 7.

Reference is made back to FIGS. 1 and 2. The method M proceeds to the step S6 where the EUV mask 200 is scanned in the inspection tool 100T to obtain a post-exposure mask image after the EUV lithography process. As illustrated at step S6, the scanning process may include sequentially capturing sub-images of plural interested regions of the EUV mask 200. For example, the mask stage 120 may move the EUV mask 200, such that the interested regions of the EUV mask 200 are sequentially moved to a inspect position where the light from the light source 140 is impinged. The sub-images of the interested regions of the EUV mask 200 are combined as a whole mask image, which is referred to as a golden mask image or a reference mask image. At this stage, since the mask image is scanned after an EUV lithography process, the mask image may be referred to as a post-exposure mask image. And, the sub-images of the interested regions of the EUV mask 200 at this stage may be referred to as post-exposure sub-images. FIG. 6B is a post-exposure sub-image of the interested region of the mask according to some embodiments of the present disclosure. Since the EUV mask 200 has experienced one or more lithography processes, the absorptive pattern 200F is shown with some defects DF in FIG. 6B.

The method M proceeds to the step S7, where a defect image is determined according to the post-exposure mask image. The processing system 160 and/or the controller 190 may be configured to execute the computer readable instructions to analyze characteristics of the post-exposure mask image to determine a defect image. The defect image may show various defect characteristics (e.g., defect type, size, depth, or shape), defect distribution, and a number of defects. In some embodiments, the processing system 160 and/or the controller 190 uses the golden image (referring to FIG. 6A), which may be stored in memory, to determine the defect image. For example, the post-exposure sub-images at the interested regions of the mask 200 are respective compared with the golden sub-images at the interested regions of the mask 200, and the comparison processes yield defect sub-images as their comparison results. The defect sub-images may be combined to obtain a whole defect image. FIG. 6C is a defect sub-image of the interested region of the mask 200 according to some embodiments of the present disclosure. The distribution of the detects DF on the mask 200 after the EUV lithography process can be observed. In some alternative examples, a whole post-exposure mask image is compared to a whole golden mask image, and the comparison process yields a whole defect image as its comparison result.

In some other embodiments, the processing system 160 and/or the controller 190 uses an algorithm or a look-up table, stored in memory, to determine defect characteristics. In such embodiments, the steps S4, where the EUV mask 200 is scanned in the inspection tool 100T to obtain a golden mask image, can be omitted.

The method M proceeds to the step S8 where it is determined whether the defect characteristics, the defect distribution, and/or the defect number in the defect image is acceptable. The defect characteristics, defect distribution, and/or the defect number may be compared with one or more defect detection threshold values. In some examples, an average size of the defect may be compared with a threshold size value. In some examples, a number of the defects may be compared with a threshold number value. In some examples, a uniformity of a distribution of the defects may be compared with a threshold uniformity value.

If the defect characteristics, defect distribution, and/or the defect number exceed the defect detection threshold values, the defect characteristics, the defect distribution, and/or the defect number in the defect image may be considered as unacceptable, and the method M proceeds to the step S9 where the EUV mask 200 is sent for repair, and the operator may turn to use a next EUV mask. The repair operation may include cleaning surfaces of the EUV mask 200.

If the defect characteristics, defect distribution, and/or the defect number do not exceed the defect detection threshold values, the defect characteristics, the defect distribution, and/or the defect number in the defect image may be considered as acceptable, and the method M goes back to the step S5 to perform another EUV lithography process by using the EUV mask 200. Then, the steps S5-S8 may be repeated. The repeated step S6 may be performed in the inspection tool 100T under the environmental pressure control. The steps S5-S8 may repeat several times until the defect characteristics, defect distribution, and/or the defect number turn to exceed the defect detection threshold values, and ended at the step S9.

The method M proceeds to the step S10 where a failing ratio of inspection is checked after scanning the EUV mask 200 several times, and it is determined whether the failing ratio of inspection is too high. In some cases, aberration instability may distort, darken, or blur the inspected image, which may fail the inspection. In some embodiments, the inspection tool 100T may provide an aberration variation at the step S6 where the EUV mask 200 is scanned. The aberration variation is recorded. A predetermined aberration variation range may be considered as a criteria determining whether the inspection succeed or fail. The aberration variation is recorded and compared with the predetermined aberration variation range. When the aberration variation is in the predetermined aberration variation range, the inspection at step S6 is determined as a successful event. When the aberration variation is out of the predetermined aberration variation range, the inspection at step S6 is determined as a failing event. After repeating the step S6 several times (obtaining plural post-exposure mask images), successful events and failing events are recorded of inspection, and a failing ratio of inspection can be obtained, for example, by dividing a number of the failing events by a sum of a number of the successful events and the number of the failing events. If the failing ratio of inspection is too high (e.g., higher than a threshold value, for example, ranging from 5% to about 30%, such as about 20%), the method M may proceed to step S11 where the inspection tool 100T is monitored and calibrated. If the failing ratio of inspection is less than the threshold value, the method M may proceed to step S7 where a defect image is determined according to the post-exposure mask image.

In some embodiments, under the environmental pressure control at step S3, the pressure difference is maintained within an acceptable range, and the aberration variation can be kept within predetermined aberration variation range, thereby lowering a failing ratio of inspection. In such embodiments, the inspect tool 100T has a high stability, and the steps S10 and S11 may be omitted.

FIG. 7 is a schematic view of a lithography system 300 according to some embodiments of the present disclosure. The lithography system 300 may also be referred to as a scanner that is operable to perform lithography exposing processes with respective radiation source and exposure mode. In some embodiments, the lithography system 300 is an EUV lithography system designed to expose a resist layer by EUV light (or EUV radiation). The resist layer is a material sensitive to the EUV light. The EUV lithography system 300 employs a radiation source 400 to generate EUV light EL, such as EUV light having a wavelength ranging between about 1 nm and about 100 nm. In certain examples, the EUV light EL has a wavelength range centered at about 13.5 nm. Accordingly, the radiation source 400 is also referred to as an EUV radiation source 400. The EUV radiation source 400 may utilize a mechanism of laser-produced plasma (LPP) to generate the EUV radiation.

The lithography system 300 also employs an illuminator 310. In some embodiments, the illuminator 310 includes various reflective optics such as a single mirror or a mirror system having multiple mirrors in order to direct the EUV light EL from the radiation source 400 onto a mask stage 320, particularly to a mask 200 secured on the mask stage 320. In some embodiments, the mask stage 320 includes an electrostatic chuck (e-chuck) used to secure the mask 200.

The lithography system 300 also includes a projection optics module (or projection optics box (POB)) 340 for imaging the pattern of the mask 200 onto a semiconductor substrate W secured on a substrate stage (or wafer stage) 350 of the lithography system 300. The POB 340 includes reflective optics in the present embodiments. The light EL that is directed from the mask 200 and carries the image of the pattern defined on the mask 200 is collected by the POB 340. The illuminator 310 and the POB 340 may be collectively referred to as an optical assembly of the lithography system 300.

In the present embodiments, the semiconductor substrate W is a semiconductor wafer, such as a silicon wafer or other type of wafer to be patterned. The semiconductor substrate W is coated with a resist layer sensitive to the EUV light EL in the present embodiments. Various components including those described above are integrated together and are operable to perform lithography exposing processes.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that pressure sensors are installed to monitor the fluctuation of environmental pressure surrounding the objective lens, and the thrust force can be controlled according to the monitored fluctuation of environmental pressure by adjusting the power of the air fan, thereby effectively reducing rates of the inspection scan failure caused by aberration. Another advantage is that the rates of the inspection scan failure is reduced by an inline aggressive control. Still another advantage is that tool availability is improved by reducing rates of the inspection scan failure. Still another advantage is that cost reduction can be achieving by saving time for calibrating the tool.

According to some embodiments of the present disclosure, a method for inspecting a mask is provided. The method includes placing the mask on a stage of an inspection tool; using a fan assembly, introducing a gas flow into the inspection tool; performing an environmental pressure control over the inspection tool; and using a detector, capturing an image of the mask. The environmental pressure control includes monitoring an in-tool pressure inside the inspection tool and an out-tool pressure outside the inspection tool; determining whether the pressure difference between the in-tool pressure and the out-tool pressure is out of an acceptable range; and in response the determination determines that the pressure difference between the in-tool pressure and the out-tool pressure is out of the acceptable range, adjusting the power of the fan assembly.

According to some embodiments of the present disclosure, a method for inspecting a mask is provided. The method includes placing the mask on a stage of an inspection tool; using a fan assembly, introducing a gas flow into the inspection tool by a first gas trust force; after introducing the gas flow into the inspection tool by the first gas trust force, using the fan assembly, introducing the gas flow into the inspection tool by a second gas trust force, wherein the second gas trust force is different from the first gas trust force; and capturing an image of the mask on the stage of the inspection tool.

According to some embodiments of the present disclosure, a system includes an inspection tool, a fan assembly, a first pressure sensor, and a second pressure sensor. The inspection tool includes a stage, a light source, a detector, and an optical assembly. The optical assembly is configured for directing a light from the light source to a mask on the stage and directing a light reflected by the mask to the detector. The fan assembly is configured for introducing a gas flow into the inspection tool. The first pressure sensor is inside the inspection tool and configured for detecting an in-tool pressure. The second pressure is outside the inspection tool and configured for detecting an out-tool pressure. The controller is coupled with the fan assembly, the first pressure sensor, and the second pressure sensor. The controller is configured for adjusting a power of the fan assembly according to the in-tool pressure and the out-tool pressure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for inspecting a mask, comprising:
placing the mask on a stage of an inspection tool;
using a fan assembly, introducing a gas flow into the inspection tool;
performing an environmental pressure control over the inspection tool, wherein the environmental pressure control comprises:
monitoring an in-tool pressure inside the inspection tool and an out-tool pressure outside the inspection tool;
determining whether a pressure difference between the in-tool pressure and the out-tool pressure is out of an acceptable range; and
in response the determination determines that the pressure difference between the in-tool pressure and the out-tool pressure is out of the acceptable range, adjusting a power of the fan assembly; and
capturing a first image of the mask on the stage of the inspection tool.

2. The method of claim 1, further comprising:
directing a light to the mask through an optical assembly in the inspection tool.

3. The method of claim 1, wherein adjusting the power of the fan assembly comprises:
decreasing the power of the fan assembly when the in-tool pressure is greater than the out-tool pressure.

4. The method of claim 1, wherein adjusting the power of the fan assembly comprises:
increasing the power of the fan assembly when the in-tool pressure is less than the out-tool pressure.

5. The method of claim 1, wherein capturing the first image of the mask is performed under the environmental pressure control.

6. The method of claim 1, further comprising:
prior to placing the mask on the stage of the inspection tool, performing a first lithography process by using the mask.

7. The method of claim 1, further comprising:
after capturing the first image of the mask, performing a second lithography process by using the mask.

8. The method of claim 7, further comprising:
after the second lithography process, capturing a second image of the mask, wherein capturing the second image of the mask is performed under the environmental pressure control.

9. A method for inspecting a mask, comprising:
placing the mask on a stage of an inspection tool;
using a fan assembly, introducing a gas flow into the inspection tool by a first gas trust force;
after introducing the gas flow into the inspection tool by the first gas trust force, using the fan assembly, introducing the gas flow into the inspection tool by a second gas trust force, wherein the second gas trust force is different from the first gas trust force; and
capturing an image of the mask on the stage of the inspection tool.

10. The method of claim 9, wherein introducing the gas flow into the inspection tool by the first gas trust force and introducing the gas flow into the inspection tool by the second gas trust force are performed when the mask is on the stage of the inspection tool.

11. The method of claim 9, further comprising:
after introducing the gas flow into the inspection tool by the second gas trust force, using the fan assembly, introducing the gas flow into the inspection tool by a third gas trust force, wherein the third gas trust force is different from the second gas trust force.

12. The method of claim 11, wherein the first gas trust force is greater than the second gas trust force, and the second gas trust force is greater than the third gas trust force.

13. The method of claim 11, wherein the first gas trust force is greater than the second gas trust force, and the second gas trust force is less than the third gas trust force.

14. The method of claim 9, wherein capturing the image of the mask comprises:
using a detector, receiving a light reflected by the mask through an optical assembly in the inspection tool.

15. The method of claim 9, wherein capturing the image of the mask comprises:
scanning the mask, wherein introducing the gas flow into the inspection tool by the first gas trust force and introducing the gas flow into the inspection tool by the second gas trust force are performed when the mask is scanned.

16. The method of claim 9, wherein introducing the gas flow into the inspection tool by the first gas trust force comprises providing a first power to the fan assembly, and introducing the gas flow into the inspection tool by the second gas trust force comprises providing a second power to the fan assembly, and the second power is different from the first power.

17. The method of claim 9, wherein the mask comprises a reflective multi-layer.

18. A system, comprising:
an inspection tool, comprising:
a stage;
a light source;
a detector; and
an optical assembly configured for directing a light from the light source to a mask on the stage and directing a light reflected by the mask to the detector;
a fan assembly configured for introducing a gas flow into the inspection tool;
a first pressure sensor inside the inspection tool and configured for detecting an in-tool pressure;
a second pressure sensor outside the inspection tool and configured for detecting an out-tool pressure; and
a controller coupled with the fan assembly, the first pressure sensor, and the second pressure sensor, wherein the controller is configured for adjusting a power of the fan assembly according to the in-tool pressure and the out-tool pressure.

19. The system of claim 18, wherein the optical assembly comprises an objective lens.

20. The system of claim 18, wherein the fan assembly is located on a top side of a cabinet of the inspection tool.
